(19) United States
(12) Patent Application Publication
(10) Pub. No.: US 2024/0355694 A1
(43) Pub. Date: Oct. 24, 2024

(54) MEMORY, FABRICATION METHOD THEREOF AND MEMORY SYSTEM

(71) Applicant: YANGTZE MEMORY TECHNOLOGIES CO., LTD., Wuhan (CN)

(72) Inventors: Huayang YU, Wuhan (CN); Qingyi HUANG, Wuhan (CN); Pengzhen ZHANG, Wuhan (CN); Zhen PAN, Wuhan (CN); Xijin PENG, Wuhan (CN); Shuai HU, Wuhan (CN); Mengting WANG, Wuhan (CN); Qikang HUANG, Wuhan (CN)

(21) Appl. No.: 18/366,112

(22) Filed: Aug. 7, 2023

(30) Foreign Application Priority Data
Apr. 23, 2023 (CN) 2023104464644

(51) Int. Cl. H01L 23/31; H01L 21/56; H10B 41/20; H10B 41/35; H10B 41/40; H10B 43/20; H10B 43/35; H10B 43/40

(52) U.S. Cl. CPC H01L 23/3157; H01L 21/56; H10B 41/20; H10B 41/35; H10B 41/40; H10B 43/20; H10B 43/35; H10B 43/40

(57) ABSTRACT

The present disclosure discloses a memory, a fabrication method thereof, and a memory system. According to an example, the memory includes a substrate, a device layer, a padding layer and a buffering protection layer. The device layer is disposed on the substrate, the padding layer is disposed at a first side of the device layer, the buffering protection layer is disposed on a second side of the device layer and a side of the padding layer away from the substrate. The padding layer is disposed to be adjacent to the device layer in a direction parallel to the substrate.

### CROSS-REFERENCE TO RELATED APPLICATIONS

The present application claims priority to Chinese Patent Application No. 2023104464644, which was filed Apr. 23, 2023, is titled “MEMORY, FABRICATION METHOD THEREOF AND MEMORY SYSTEM,” and is hereby incorporated herein by reference in its entirety.

### TECHNICAL FIELD

The present disclosure relates to the field of semiconductor technology, and in particular to a memory, a fabrication method thereof and a memory system.

### BACKGROUND

During fabrication of a memory, a substrate is thinned from backside thereof after the fabrication of a device structure on the substrate. The thinned memory facilitates an ultra-thin package, efficient light transmission, better heat dissipation and higher electrical performance.

### SUMMARY

Examples of the present disclosure provide a memory, a fabrication method thereof, and a memory system in which a buffering protection layer can cover a device layer to improve a protecting effect by a padding layer for reducing a level difference at an edge of the device layer.

An example of the present disclosure provides a memory, comprising: a substrate; a device layer disposed on the substrate; a padding layer disposed at a first side of the device layer; and a buffering protection layer disposed on a second side of the device layer and a side of the padding layer away from the substrate, wherein the padding layer is disposed to be adjacent to the device layer in a direction parallel to the substrate.

In an example of the present disclosure, a surface of the device layer away from the substrate has a first distance from the substrate, and a surface of the padding layer away from the substrate has a second distance from the substrate, wherein the first distance is greater than or equal to the second distance.

In an example of the present disclosure, a difference between the first distance and the second distance is smaller than or equal to 20 microns.

In an example of the present disclosure, the padding layer comprises a photoresist.

In an example of the present disclosure, the photoresist has a viscosity greater than or equal to 1000 cp.

In an example of the present disclosure, the photoresist comprises a negative photoresist.

In an example of the present disclosure, the device layer comprises a peripheral circuit unit and a memory array unit; the buffering protection layer covers a side of both the memory array unit and the padding layer away from the substrate; and the memory further comprises a packaging layer at least covering a side of the buffering protection layer away from the substrate.

In an example of the present disclosure, the padding layer is disposed on the substrate and surrounds the device layer.

Examples of the present disclosure further provide a method of fabricating a memory, comprising: forming a device layer on a substrate; forming a padding layer at a first side of the device layer and adjacent to the device layer in a direction parallel to the substrate; and forming a buffering protection layer on a second side of the device layer and a side of the padding layer away from the substrate.

In an example of the present disclosure, forming the device layer on the substrate further comprises: forming a peripheral circuit unit on the substrate; forming a memory array unit; and bonding the memory array unit with the peripheral circuit unit, with the memory array unit located on a side of the peripheral circuit unit away from the substrate.

In an example of the present disclosure, forming the padding layer at the first side of the device layer further comprises: forming a photoresist covering the device layer and the substrate; and removing the photoresist of the device layer away from the substrate to form the padding layer on the substrate, with the padding layer surrounding the device layer.

In an example of the present disclosure, in forming the photoresist covering the device layer and the substrate, the photoresist has a viscosity greater than or equal to 1000 cp.

In an example of the present disclosure, in forming the photoresist covering the device layer and the substrate, the photoresist comprises a negative photoresist.

In an example of the present disclosure, removing the photoresist of the device layer away from the substrate comprises: performing an exposure and development processing on the photoresist to remove the photoresist of the device layer away from the substrate.

In an example of the present disclosure, in forming the padding layer at the first side of the device layer, a surface of the device layer away from the substrate has a first distance from the substrate, and a surface of the padding layer of the padding layer away from the substrate has a second distance from the substrate, wherein the first distance is greater than or equal to the second distance, and a difference between the first distance and the second distance is smaller than or equal to 20 microns.

In an example of the present disclosure, forming the buffering protection layer on the second side of the device layer and the side of the padding layer away from the substrate further comprises: attaching a protective adhesive layer to a side of the buffering protection layer away from the substrate; thinning the substrate from a side of the substrate away from the device layer; removing the protective adhesive layer; and forming a packaging layer on a side of the buffering protection layer away from the substrate.

Examples of the present disclosure further provide a memory system, comprising a memory and a controller, the controller being coupled to the memory and configured to control the memory to store data.

In the present disclosure, a padding layer is disposed on a substrate and adjacent to a device layer in a direction parallel to the substrate, so as to form a buffer for a difference in height between an edge of the device layer and the substrate. As a result, the buffering protection layer undergoes a reduced level difference when extending to cover the edge of the device layer and can cover the device layer and the padding layer effectively, so as to enhance a protection of the buffering protection layer for the device layer. Since the level difference between the edge of the device layer and the substrate is reduced, a yield of a subsequent packaging can be improved and the yield and stability of the memory can be improved.

### BRIEF DESCRIPTION OF THE DRAWINGS

Implementations of the present disclosure will be described in detail hereafter with reference to accompanying drawings, so that technical solutions of the present disclosure will become apparent.

FIGS. 1 to 3 are schematic structural diagrams illustrating a process of fabricating a memory provided in some examples.

FIG. 4 is a schematic structural diagram of a memory provided in some examples of the present disclosure.

FIG. 5 is a flowchart illustrating a method of fabricating a memory provided in some examples of the present disclosure.

FIGS. 6 to 10 are schematic structural diagrams illustrating a process of fabricating a memory provided in some examples of the present disclosure.

FIG. 11 is a schematic structural diagram of a memory system provided in some examples of the present disclosure.

FIG. 12 is a flowchart illustrating a method of fabricating a memory provided in some examples of the present disclosure.

### DETAILED DESCRIPTION

Technical solutions in examples of the present disclosure will be described clearly and completely below in connection with accompanying drawings of the examples of the present disclosure. The examples to be described are only some, not all, examples of the present disclosure. All other examples obtained by those skilled in the art based on the examples of the present disclosure without any creative works fall within the scope claimed by the present disclosure.

The disclosure provides many different implementations or examples for implementing different structures of the present disclosure. To simplify the disclosure of the present disclosure, components and configurations of specific examples will be described hereafter. They are only examples and are not for limiting the present disclosure. Moreover, in the description of the present disclosure, reference numerals and/or characters may be used repeatedly in different examples. The repetition is for the purpose of simple and clear description rather than indicating any relationships between the implementations and/or configurations in discuss. Moreover, although specific examples of various processes and materials may be provided in the present disclosure, it can be realized by those skilled in the art that other processes and/or materials may be used.

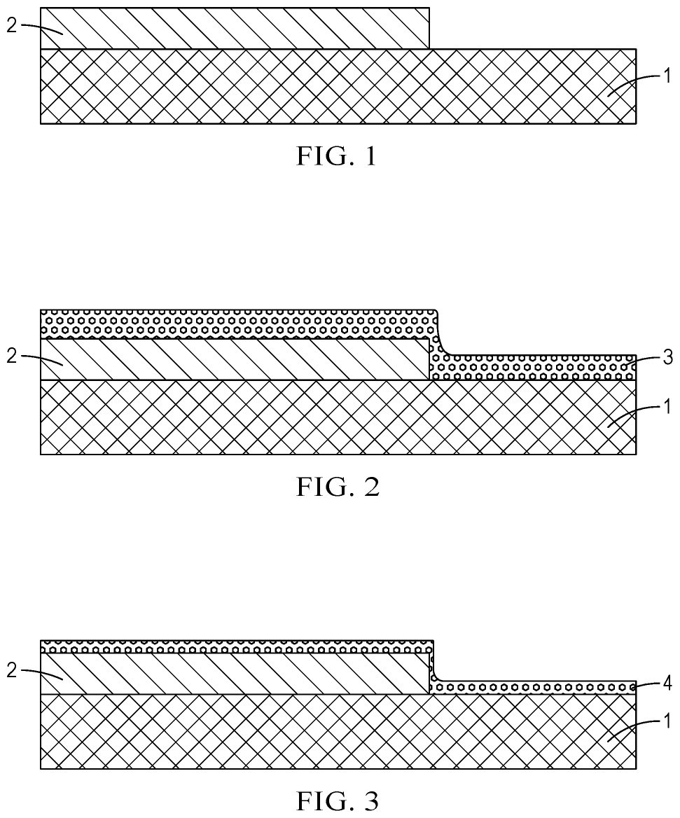

With reference to FIGS. 1 to 3, during a fabrication process of a memory, a device layer 2 may be formed on a substrate 1. When a portion of the device layer 2 is cut off at an edge of the device layer 2, a relatively larger level difference, e.g., a step, may be formed at the edge of the device layer 2. Due to requirements of a subsequent packaging, the substrate 1 may be thinned. Before the thinning of the substrate 1, the device layer 2 and the substrate 1 may be first coated with a buffering material 3 that is made into a film to serve as a buffering layer 4. During the thinning process of the substrate 1, the buffering layer 4 may protect the device layer 2. However, due to the relatively larger level difference between the edge of the device layer 2 and the substrate 1, the buffering layer 4 has a poorer covering effect at the step, and thus has a reduced protection effect. Moreover, the level difference may affect a yield of the subsequent packaging.

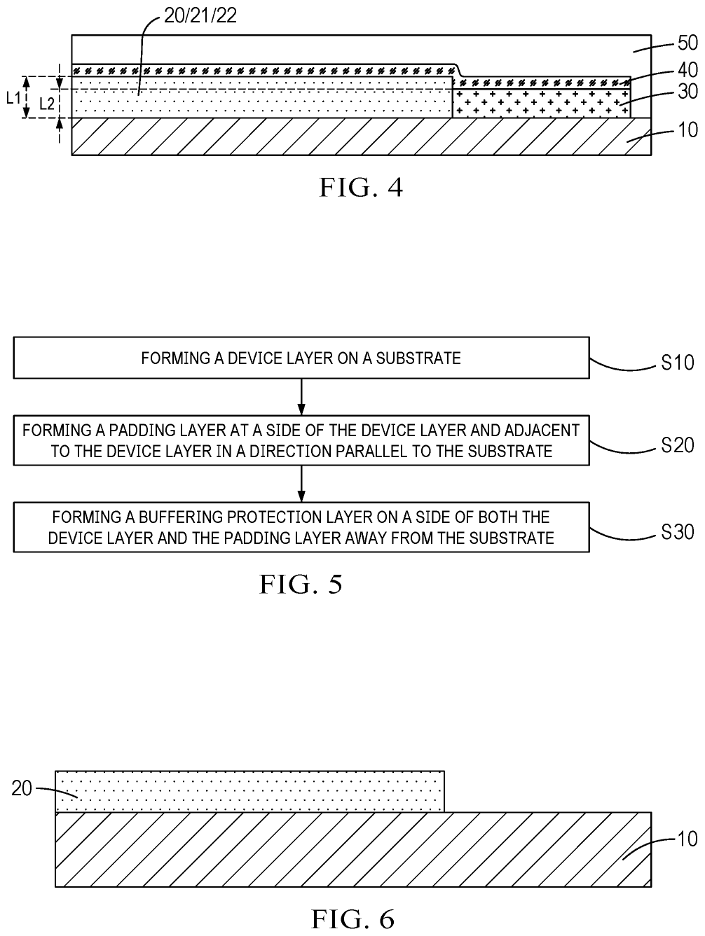

As described above, some examples of the present disclosure provide a memory that includes a substrate 10, a device layer 20, a padding layer 30 and a buffering protection layer 40, as shown in FIG. 4.

The device layer 20 is disposed on the substrate 10, the padding layer 30 is disposed at a side of the device layer 20, and the buffering protection layer 40 is disposed on a side of both the device layer 20 and the padding layer 30 away from the substrate 10.

Furthermore, the padding layer 30 is disposed adjacent to the device layer 20 in a direction parallel to the substrate 10.

In an implementation of an example of the present disclosure, the padding layer 30 is disposed on the substrate 10 and adjacent to the device layer 20 in the direction parallel to the substrate 10, so as to form a buffer for a difference in height between an edge of the device layer 20 and the substrate 10. As a result, the buffering protection layer 40 undergoes a reduced level difference when extending to cover the edge of the device layer 20 and can cover the device layer 20 and the padding layer 30, so as to enhance a protection of the buffering protection layer 40 for the device layer 20. Because the level difference between the edge of the device layer 20 and the substrate 10 is reduced, the yield of the subsequent packaging is improved and the yield and stability of the memory are improved.

In an example, with continuous reference to FIG. 4, the memory provided by an example of the present disclosure includes a substrate 10 and a device layer 20, a padding layer 30 and a buffering protection layer 40 disposed on the substrate 10.

The substrate 10 may include, but not limited to, a semiconductor material, including, for example, silicon (such as a single crystal silicon, a polysilicon or a doped polysilicon), silicon germanium (SiGe), gallium arsenide (GaAs), germanium (Ge), a silicon on insulator (SOI), a germanium on insulator (GOI) or any combination thereof.

The device layer 20 is disposed on a side of the substrate 10, and includes, but is not limited to, a peripheral circuit unit 21 and a memory array unit 22 which are bonded with each other. The peripheral circuit unit 21 is disposed on the substrate 10, and the memory array unit 22 is disposed on a side of the peripheral circuit unit 21 away from the substrate 10.

In some examples, the peripheral circuit unit 21 may include any suitable digital, analog and/or mixed signal peripheral circuit disposed on the substrate 10 and configured to operate a three-dimensional (3D) memory, and the memory array unit 22 may include a stack, in which a plurality of gate layers, a plurality of channel structures and the like are formed.

The memory provided in some examples of the present disclosure may be a 3D memory, for example, a 3D NAND memory based on an X-tacking architecture. The memory array unit 22 and the peripheral circuit unit 21 may be bonded face to face to form a 3D memory with functional circuit modules such as a logic module, a register and the like.

In some examples of the present disclosure, the device layer 20 is disposed on the substrate 10 and protrudes above a surface of the substrate 10, which thus may form a step, e.g., a level difference between the edge of the device layer 20 and the substrate 10.

Furthermore, the padding layer 30 is disposed on a side of the substrate 10 on which the device layer 20 is disposed, and the padding layer 30 is adjacent to the device layer 20 in a direction parallel to the substrate 10. In some examples, the padding layer 30 may adjoin the device layer 20. For example, the sides of the padding layer 30 and the device layer 20 proximate to each other are in contact.

A surface of the device layer 20 at a side away from the substrate 10 has a first distance L1 from the substrate 10, and a surface of the padding layer 30 at a side away from the substrate 10 has a second distance L2 from the substrate 10, wherein the first distance L1 is greater than or equal to the second distance L2. For example, the surface of the padding layer 30 at a side away from the substrate 10 may be lower than the surface of the device layer 20 at a side away from the substrate 10, so that a step having a relatively larger height may be converted into two steps having a relatively smaller height. Therefore, the padding layer 30 may function to buffer and reduce the level difference between the edge of the device layer 20 and the substrate 10.

As described above, the buffering protection layer 40 is configured to cover a side of both the device layer 20 and the padding layer 30 away from the substrate 10, and can better cover the device layer 20 and the padding layer 30 to protect the device layer 20 due to the reduced level difference between the edge of the device layer 20 and the substrate 10.

The buffering protection layer 40 may include, but not limited to, any one of polyimide, polybenzoxazole and phenol.

In some examples, the padding layer 30 is disposed on the substrate 10 and surrounds the device layer 20, so as to serve as a buffer for the level difference at the periphery of the device layer 20 and enable the buffering protection layer 40 to protect the device layer 20 at its periphery.

In some examples, the difference between the first distance L1 and the second distance L2 is smaller than or equal to 20 microns to provide a smaller level difference between the device layer 20 and the padding layer 30, so that the buffering protection layer 40 can cover the edge of the device layer 20. This may increase a film forming yield of the buffering protection layer 40 and the protecting effect of the buffering protection layer 40 for the device layer 20, so as to improve a stability and yield of the memory.

In some examples, the padding layer 30 may include, but is not limited to, a photoresist including a negative photoresist and having a viscosity greater than or equal to 1000 cp, so that the padding layer 30 may be formed by patterning the photoresist through an exposure and development process and the like, and the forming process of the padding layer 30 may be simplified.

Further, the memory may include a packaging layer 50 that at least covers a side of the buffering protection layer 40 away from the substrate 10 to provide a packaging protection for the memory. The packaging layer 50 can cover the edge of the device layer 20 due to the reduced level difference between the edge of device layer 20 and the substrate 10. As a result, the film forming yield of the packaging layer 50 and the packaging protecting effect of the packaging layer 50 for the device layer 20 can be improved.

In some examples of the present disclosure, some functional layers such as a wiring layer and the like may be formed between the packaging layer 50 and the buffering protection layer 40. However, there is no limitation in this respect. The present disclosure is described and illustrated by an example, in which the packaging layer 50 covers the buffering protection layer 40.

As described above, in some examples of the present disclosure, the padding layer 30 is disposed on the substrate 10 and adjacent to the device layer 20 in the direction parallel to the substrate 10, so as to form a buffer for the difference in height between the edge of the device layer 20 and the substrate 10. As a result, the buffering protection layer 40 undergoes a reduced level difference when extending to cover the edge of the device layer 20 and can cover the device layer 20 and the padding layer 30 effectively, so as to enhance a protection of the buffering protection layer 40 for the device layer 20. Because the level difference between the edge of the device layer 20 and the substrate 10 is reduced, the yield of the subsequent packaging can be improved and the yield and stability of the memory can be improved.

In addition, some examples of the present disclosure further provide a method of fabricating a memory that may be the memory described in the examples above. With reference to FIGS. 4, 5, and 12, the method of fabricating the memory may include: forming a device layer 20 on a substrate 10; forming a padding layer 30 at a side of the device layer 20 and adjacent to the device layer 20 in a direction parallel to the substrate 10; and forming a buffering protection layer 40 on a side of both the device layer 20 and the padding layer 30 away from the substrate 10.

In some examples of the present disclosure, a level difference at the edge of the device layer 20 may be reduced by the formed padding layer 30, so that the coverage and protection effects of the buffering protection layer 40 can be improved and the yield of the memory can be improved.

In an example, with reference to FIGS. 4, 5, 10, and 12 the method of fabricating the memory includes the following operations.

At operation S10, a device layer 20 is formed on a substrate 10.

In operation S10, the substrate 10 is first provided, and the substrate 10 may include, but is not limited to, a semiconductor material, including, for example, silicon (such as a single crystal silicon, a polysilicon or a doped polysilicon), silicon germanium (SiGe), gallium arsenide (GaAs), germanium (Ge), a silicon on insulator (SOI), a germanium on insulator (GOI) or any combination thereof.

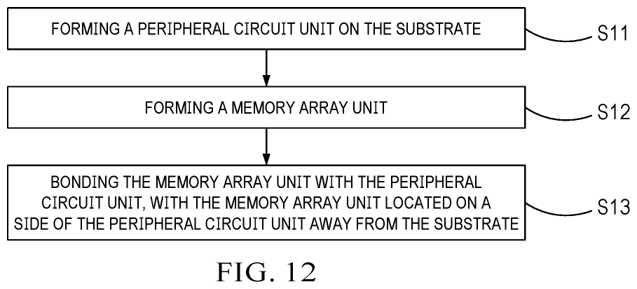

With reference to FIG. 12, at operation S11, a peripheral circuit unit 21 may be formed on the substrate 10, and the peripheral circuit unit 21 may include any suitable digital, analog and/or mixed signal peripheral circuit disposed on the substrate 10 and configured to operate a 3D memory.

At operation S12, a memory array unit 22 may be formed to include, but not limited to, a stack, in which, for example, a plurality of gate layers, a plurality of channel structures and the like are formed

In some examples of the present disclosure, a chronological order in which the operation of forming the peripheral circuit unit 21 on the substrate 10 and the operation of forming the memory array unit 22 are performed is not limited and can be selected according to practical demands.

Subsequently, at operation S13, the memory array unit 22 is bonded to a side of the peripheral circuit unit 21 away from the substrate 10, and the memory array unit 22 is bonded to the peripheral circuit unit 21 to form a device layer 20 on the substrate 10, as shown in FIG. 6.

Returning to FIG. 5, at operation S20, a padding layer 30 is formed on a side of the substrate 10 having the device layer 20 formed thereon, and is disposed to be adjacent to the device layer 20 in a direction parallel to the substrate 10.

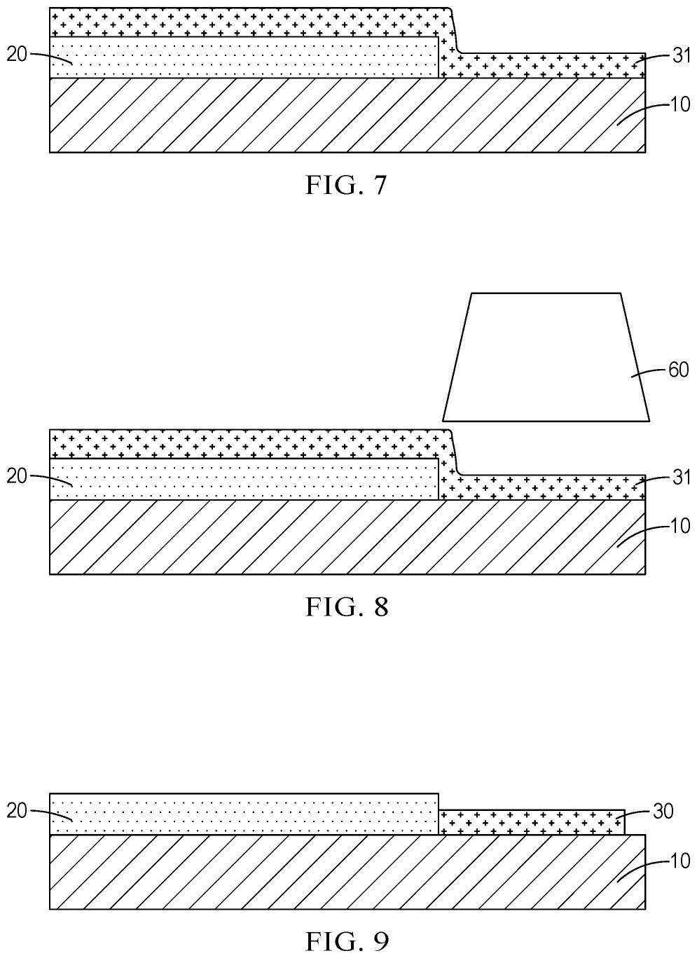

In operation S20, a photoresist 31 is first formed to cover the device layer 20 and the substrate 10, as shown in FIG. 7.

The photoresist 31 may be a negative photoresist, and may have a viscosity greater than or equal to 1000 cp so that the photoresist 31 may be deposited by a nozzle of a conventional machine, with the nozzle modified.

Subsequently, the photoresist 31 at a side of the device layer 20 is exposed by an exposure equipment 60, as shown in FIG. 8. The exposed portion of the photoresist 31 is located at the side of the device layer 20 in the direction parallel to the substrate 10.

Subsequently, the photoresist 31 is developed by a developing liquid. Because the photoresist 31 is a negative photoresist, the exposed portion of the photoresist 31 at the side of the device layer 20 will not dissolve in the developing liquid and thus may remain on the substrate 10 to form the padding layer 30. The unexposed portion of the photoresist 31 dissolves in the developing liquid and then is washed away, as shown in FIG. 9.

A surface of the device layer 20 at a side away from the substrate 10 has a first distance L1 from the substrate 10, and a surface of the padding layer 30 at a side away from the substrate 10 has a second distance L2 from the substrate 10, wherein the first distance L1 is greater than or equal to the second distance L2.

In some examples, a difference between the first distance L1 and the second distance L2 is smaller than or equal to 20 microns to provide a smaller level difference between the device layer 20 and the padding layer 30.

At operation S30, a buffering protection layer 40 is formed on a side of both the device layer 20 and the padding layer 30 away from the substrate 10.

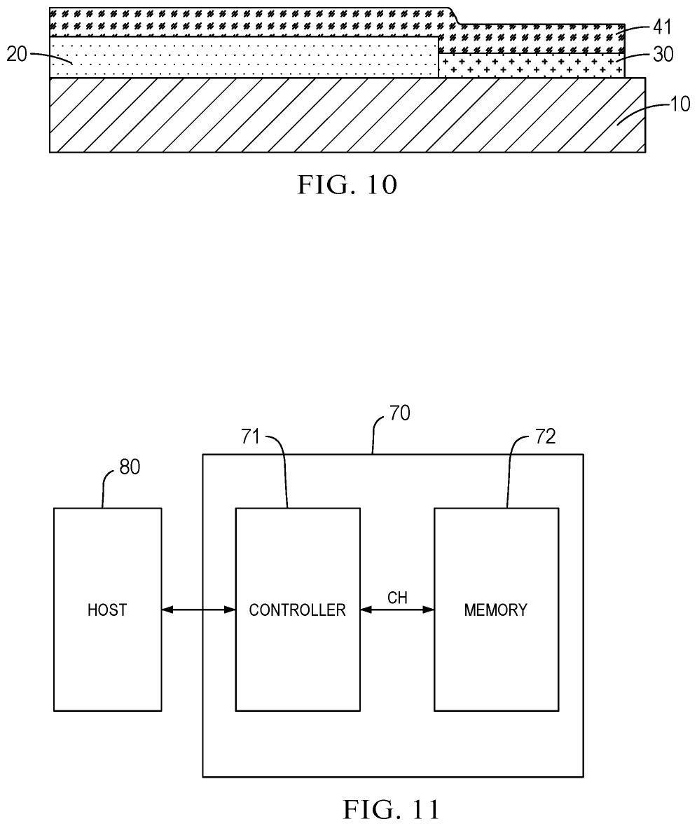

In operation S30, a buffering protection material 41 is deposited on a side of both the device layer 20 and the padding layer 30 away from the substrate 10, as shown in FIG. 10.

In some examples, the buffering protection material 41 may include, but not limited to, any one of polyimide, polybenzoxazole and phenol.

Then, the buffering protection material 41 is made into a film as the buffering protection layer 40, for example, by a curing processing including at least one of a light curing or a thermal curing. Because a surface of the padding layer 30 at a side away from the substrate 10 may be lower than a surface of the device layer 20 at a side away from the substrate 10, a step having a relatively larger height may be converted into two steps having a relatively smaller height, so that the padding layer 30 may serve as a buffer for buffering the level difference between the edge of the device layer 20 and the substrate 10. The difference between the first distance L1 and the second distance L2 is smaller than or equal to 20 microns to provide a smaller level difference between the device layer 20 and the padding layer 30, so that the buffering protection layer 40 can cover the edge of the device layer 20, which further improves the film forming yield of the buffering protection layer 40 and the protecting effect of the buffering protection layer 40 for the device layer 20, so as to improve a stability and yield of the memory.

Further, a protective adhesive layer is attached to a side of the buffering protection layer 40 away from the substrate 10, and then the substrate 10 is thinned from a side of the substrate 10 away from the device layer 20, as shown in FIG. 4, to facilitate the subsequent packaging process. Then, the protective adhesive layer is removed. Finally, a packaging layer 50 is formed at least on a side of the buffering protection layer 40 away from the substrate 10 to provide a packaging protection for the memory and can cover the edge of the device layer 20 due to the buffered level difference between the edge of device layer 20 and the substrate 10. As a result, the film forming yield of the packaging layer 50 and the packaging protecting effect of the packaging layer 50 for the device layer 20 are improved.

Additionally, some examples of the present disclosure further provide a memory system, and the memory system includes a memory 72 and a controller 71 coupled to the memory 72 and configured to control the memory 72 to store data, as shown in FIG. 11. The memory 72 is a memory obtained by using the method of fabricating a memory described in the examples above or is the memory described in the examples above.

In an example, the controller 71 may control the memory 72 through a channel CH, and the memory 72 may operate under the control of the controller 71 in response to requests from a host 80. The memory 72 may receive a command CMD and an address ADDR through the channel CH from the controller 71, and access a region of a memory array selected in response to the address. In other words, the memory 72 may execute an internal operation corresponding to the command on the region selected based on the address.

In some examples, the memory system may be implemented to include, for example, but not limited to, a universal Flash storage (UFS) device, an solid state drive (SSD), a multimedia card in the form of MMC, eMMC. RS-MMC or MMCmicro, a secure digital card in the form of SD, miniSD or microSD, a memory device of the personal computer memory card international association (PCMCIA) card type, a memory device of the peripheral component interconnect (PCI) type, a memory device of the PCI-E type, a compact flash (CF) card, a smart media card or a memory stick.

In an example, the above-described memory system may be used in an end product such as a computer, a television, a set top box, a vehicle-mounted terminal product or the like.

Further, some examples of the present disclosure provide an electronic apparatus including the memory system provided in examples of the present disclosure. In an example, the electronic apparatus may include, but is not limited to, a cell phone, a desktop computer, a tablet computer, a notebook computer, a server, a vehicle-mounted apparatus, a wearable apparatus, a movable power source or any other apparatus capable of data storage.

The electronic apparatus provided in some examples of the present disclosure has similar usefulness as the memory system described in some examples of the present disclosure by having the memory system disposed therein.

The examples above have been described with their respective emphases, and some contents having not been described in an example may be found in related description of some other examples.

A memory, fabrication method thereof and a memory system provided by examples of the present disclosure have been described above in detail, and examples are taken to explain the principle and implementations of the present disclosure. Description of the examples above is only used to facilitate understanding of the technical solutions and the core concept of the present disclosure. It can be understood by those of ordinary skills in the art that the technical solutions described in the foregoing various examples may be modified or have some technical features therein replaced equivalently without departing from the spirit and scope of the technical solutions in the examples of the present disclosure.

What is claimed is:

1. A memory, comprising:
a substrate;
a device layer disposed on the substrate;
a padding layer disposed at a first side of the device layer; and
a buffering protection layer disposed on a second side of the device layer and a side of the padding layer away from the substrate,
wherein the padding layer is disposed to be adjacent to the device layer in a direction parallel to the substrate.

2. The memory of claim 1, wherein a surface of the device layer away from the substrate has a first distance from the substrate, and a surface of the padding layer away from the substrate has a second distance from the substrate, wherein the first distance is greater than or equal to the second distance.

3. The memory of claim 2, wherein a difference between the first distance and the second distance is smaller than or equal to 20 microns.

4. The memory of claim 1, wherein the padding layer comprises a photoresist.

5. The memory of claim 4, wherein the photoresist has a viscosity greater than or equal to 1000 cp.

6. The memory of claim 4, wherein the photoresist comprises a negative photoresist.

7. The memory of claim 1, wherein the device layer comprises a peripheral circuit unit and a memory array unit;
the buffering protection layer covers a side of both the memory array unit and the padding layer away from the substrate; and
the memory further comprises a packaging layer covering at least a side of the buffering protection layer away from the substrate.

8. The memory of claim 1, wherein the padding layer is disposed on the substrate and surrounds the device layer.

9. A method of fabricating a memory, comprising:
forming a device layer on a substrate;
forming a padding layer at a first side of the device layer and adjacent to the device layer in a direction parallel to the substrate; and
forming a buffering protection layer on a second side of the device layer and a side of the padding layer away from the substrate.

10. The method of claim 9, wherein forming the device layer on the substrate further comprises:
forming a peripheral circuit unit on the substrate;
forming a memory array unit; and
bonding the memory array unit with the peripheral circuit unit, with the memory array unit located on a side of the peripheral circuit unit away from the substrate.

11. The method of claim 9, wherein forming the padding layer at the first side of the device layer further comprises:
forming a photoresist covering the device layer and the substrate; and
removing the photoresist of the device layer away from the substrate, to form the padding layer on the substrate, with the padding layer surrounding the device layer.

12. The method of claim 11, wherein in forming the photoresist covering the device layer and the substrate, the photoresist has a viscosity greater than or equal to 1000 cp.

13. The method of claim 11, wherein in forming the photoresist covering the device layer and the substrate, the photoresist comprises a negative photoresist.

14. The method of claim 11, wherein removing the photoresist of the device layer away from the substrate, comprises:
performing an exposure and development processing on the photoresist to remove the photoresist of the device layer away from the substrate.

15. The method of claim 9, wherein in forming the padding layer at the first side of the device layer, a surface of the device layer away from the substrate has a first distance from the substrate, and a surface of the padding layer away from the substrate has a second distance from the substrate, wherein the first distance is greater than or equal to the second distance, and a difference between the first distance and the second distance is smaller than or equal to 20 microns.

16. The method of claim 9, wherein forming the buffering protection layer on the second side of the device layer and the side of the padding layer away from the substrate further comprises:
attaching a protective adhesive layer to a side of the buffering protection layer away from the substrate;
thinning the substrate from a side of the substrate away from the device layer;
removing the protective adhesive layer; and
forming a packaging layer on a side of the buffering protection layer away from the substrate.

17. A memory system, comprising:
a memory, comprising:
a substrate;
a device layer disposed on the substrate;
a padding layer disposed at a first side of the device layer; and
a buffering protection layer disposed on a second side of the device layer and a side of the padding layer away from the substrate,
wherein the padding layer is disposed to be adjacent to the device layer in a direction parallel to the substrate; and
a controller coupled to the memory and configured to control the memory to store data.
